(19) United States
(12) Patent Application Publication
(10) Pub. No.: US 2005/0110150 A1
(43) Pub. Date: May 26, 2005

(54) Semiconductor device and PLL circuit

(76) Inventors: Yasunari Furuya, Nagano-ken (JP); Masanori Kobayashi, Nagano-ken (JP)

Correspondence Address: HARNESS, DICKEY & PIERCE, P.L.C., P.O. BOX 828, BLOOMFIELD HILLS, MI, 48303, US

(21) Appl. No.: 10/984,675

(22) Filed: Nov. 9, 2004

(30) Foreign Application Priority Data
Nov. 11, 2003 (JP) 2003-381282

(51) Int. Cl. H01L 23/48; H01L 23/52; H01L 29/40

(52) U.S. Cl. 257/758

(57) ABSTRACT

A semiconductor device is provided including a plurality of circuits constituted by a multilayer structure on a substrate. The plurality of circuits are arranged so that one wiring of a plurality of wirings between the plurality of circuits in one layer of the multilayer structure and another one wiring of the plurality of wirings in another layer of the multilayer structure do not cross each other.

### RELATED APPLICATIONS

This application claims priority to Japanese Patent Application No. 2003-381282 filed Nov. 11, 2003 which is hereby expressly incorporated by reference herein in its entirety.

### BACKGROUND

1. Field of the Invention

The present invention relates to a semiconductor device such as a phase locked loop (PLL) circuit sensitive to interference between signals, i.e., a crosstalk.

2. Related Art

FIG. 8 view shows the configuration of a semiconductor device having a conventional multilayer structure. A conventional semiconductor device 200, which is a PLL circuit or the like, is composed of a plurality of functional blocks (not shown) formed on a silicon substrate 201 by a multilayer structure, and as shown in FIG. 8, a metal wiring 202 for transferring digital signals and a metal wiring 203 for transferring analog signals extend between the plurality of functional blocks.

There are cases where the digital signal metal wiring 202 and the analog signal metal wiring 203 need to cross due to the arrangement of the above described plurality of circuit blocks, and in order to carry out the crossing, for example, the analog signal metal wiring 203 has a three-dimensional structure, as shown in FIG. 8, composed of a wiring portion 203a which extends on the silicon substrate 201 surface in a lower layer 210 of the multilayer structure, i.e., in the lower layer 210; a wiring portion 203b which extends in an upper layer 220 of the multilayer structure in parallel with the wiring portion 203a of the lower layer 210; and an “L” shaped connection portion 203c for mutually coupling an end portion of the wiring portion 203a in the lower layer 210 and an end portion of the wiring portion 203b in the upper layer 220. In addition, a shield wiring 204 is arranged between the digital signal metal wiring 202 and the analog signal wiring portion 203a in the lower layer 210 in order to avoid crosstalk from the digital signal metal wiring 202 to the analog signal wiring portion 203a.

However, because there is the possibility that crosstalk from the digital signal metal wiring 202 in the lower layer 210 to the analog signal wiring portion 203b in the upper layer 220 may arise, a shield wiring 205 needs to be arranged in the lower layer 210 in order to shield between the digital signal metal wiring 202 and the analog signal wiring portion 203b, and thereby, the silicon substrate 201 needs to be extended in the horizontal direction. This causes a problem in that the area of the silicon substrate 201 needs to be enlarged.

### SUMMARY

A first semiconductor device according to the present invention has a plurality of circuits constituted by a multilayer structure on a substrate, wherein the plurality of circuits are arranged so that one wiring of a plurality of wirings between the plurality of circuits in one layer of the multilayer structure and another wiring of the plurality of wirings in another layer of the multilayer structure do not cross each other.

Moreover, a second semiconductor device according to the present invention has a plurality of circuits constituted by a multilayer structure on a substrate, wherein the plurality of circuits are arranged so that one wiring and another wiring of a plurality of wirings between the plurality of circuits extend in the same layer of the multilayer structure.

According to the first and the second semiconductor devices of the present invention, because the plurality of circuits are arranged so that the one wiring in the one layer of the multilayer structure and the other wiring of the other layer of the multilayer structure do not cross each other, and moreover, because the plurality of circuits are arranged so that the one wiring and the other wiring extend in the same layer of the multilayer structure, a shield wiring between the one wiring and the other wiring, which would be needed if both wirings crossed, is not required. This enables the reduction of the area of the substrate as compared with the conventional art.

A first PLL circuit according to the present invention has a phase comparator, a charge pump, a filter, a voltage controlled oscillator, and a frequency divider constituted by a multilayer structure on a substrate, wherein the phase comparator, the charge pump, the filter, the voltage controlled oscillator, and the frequency divider are arranged so that one wiring of a plurality of wirings between the phase comparator, the charge pump, the filter, the voltage controlled oscillator, and the frequency divider in one layer of the multilayer structure, and another wiring of the plurality of wirings in another layer of the multilayer structure do not cross each other.

A second PLL circuit according to the present invention is the PLL circuit having a phase comparator, a charge pump, a filter, a voltage controlled oscillator, and a frequency divider constituted by a multilayer structure on a substrate, wherein the phase comparator, the charge pump, the filter, the voltage controlled oscillator, and the frequency divider are arranged so that one wiring and another wiring of a plurality of wirings between the phase comparator, the charge pump, the filter, the voltage controlled oscillator, and the frequency divider extend in the same layer of the multilayer structure.

According to the first and the second PLL circuits of the present invention, because the phase comparator, the charge pump, the filter, the voltage controlled oscillator, and the frequency divider are arranged so that the one wiring and the other wiring do not cross each other or the one wiring and the other wiring extend in the same layer of the multilayer structure, a shield wiring between the one wiring and the other wiring, which would be needed if both wirings crossed, is not needed. This enables the reduction of the area of the substrate as compared with the conventional art.

In the PLL circuit according to the above described present invention, it is desirable that the phase comparator, the charge pump, the filter, the voltage controlled oscillator, and the frequency divider are arranged so that the plurality of wirings, an input signal wiring to the phase comparator circuit, and an output signal wiring from the voltage controlled oscillator do not cross each other.

In the PLL circuit according to the above described present invention, it is desirable that the phase comparator, the charge pump, the filter, the voltage controlled oscillator, and the frequency divider are arranged so that the plurality of wirings, an input signal wiring to the phase comparator circuit, and an output signal wiring from the voltage controlled oscillator extend in the same layer of the multilayer structure.

In the PLL circuit according to the above described present invention, it is desirable that a first distance between the charge pump and the voltage controlled oscillator is longer than a second distance between two mutually adjoining members of the group including the phase comparator, the charge pump, the voltage controlled oscillator, and the frequency divider.

In the PLL circuit according to the above described present invention, it is desirable that a transistor which functions as a capacitor in the filter is provided between the charge pump and the voltage controlled oscillator.

In the PLL circuit according to the above described present invention, it is desirable that a plurality of transistors which function as a capacitor in the filter are provided in the periphery of the voltage controlled oscillator.

In the PLL circuit according to the above described present invention, it is desirable that a bypass capacitor between a power supply wiring for supplying electric power to one of the phase comparator, the charge pump, the filter, the voltage controlled oscillator, and the frequency dividers, and ground is provided near the filter.

In the PLL circuit according to the above described invention, it is desirable that the bypass capacitor is provided on the outside of a closed region virtually formed by joining the phase comparator, the charge pump, the filter, the voltage controlled oscillator, and the frequency divider.

### BRIEF DESCRIPTION OF THE DRAWINGS

FIG. 1 is a circuit diagram showing the configuration of a PLL circuit of embodiment 1.

FIG. 2 is a view schematically showing a PLL circuit wiring of embodiment 1.

FIG. 3 is a view showing the arrangement of functional blocks in the PLL circuit of embodiment 1.

FIG. 4 is a view schematically showing the structure of the PLL circuit of embodiment 2.

FIG. 5 is a view showing the arrangement of the functional blocks in the PLL circuit of embodiment 2.

FIG. 6 is a view schematically showing the structure of the PLL circuit of embodiment 3.

FIG. 7 is a view showing the arrangement of the functional blocks in the PLL circuit of embodiment 3.

FIG. 8 is a view showing the configuration of a conventional semiconductor device.

### DETAILED DESCRIPTION

Embodiments of the semiconductor device according to the present invention will be described with reference to accompanying drawings. PLL circuits of a first embodiment through a third embodiment are semiconductor devices mounted in, for example, a cellular phone ASIC, an LCD panel ASIC, a low power microcomputer IC and an LSI for clocks, or the like, and are constituted by a multilayer structure on a semiconductor substrate.

### Embodiment 1

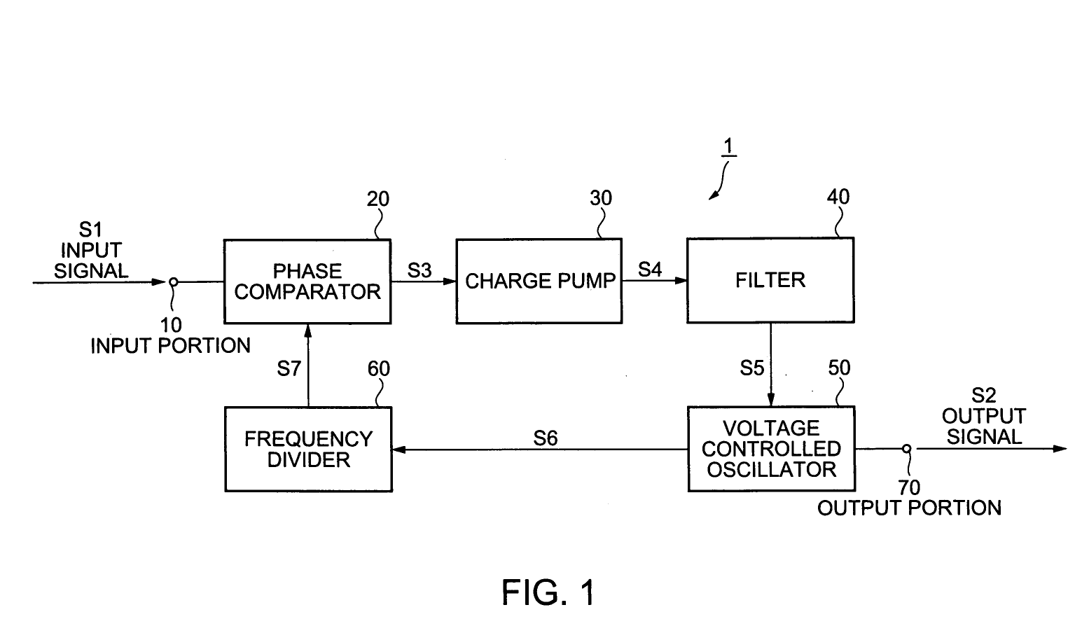

FIG. 1 is a circuit diagram showing the configuration of the PLL circuit of embodiment 1. A PLL circuit 1 of embodiment 1 has an input portion 10, a phase comparator 20, a charge pump 30, a filter 40, a voltage controlled oscillator 50, a frequency divider 60, and an output portion 70, in order to output an output signal S2, which is a multiplication of an input signal S1 based on the input signal S1 which is a reference frequency. The input portion 10 through the output portion 70 are formed by a multilayer structure on a semiconductor substrate as described above. Hereinafter, the input portion 10 through the output portion 70 will be generically called a “functional block” in order to make the description and the comprehension easy.

The input portion 10 receives, for example, from an external quarts crystal oscillator (not shown), an input signal S1 whose frequency is stabilized and which is generated by vibration of the crystal oscillator, and the input signal S1 is inputted to the phase comparator 20.

The phase comparator 20 detects the phase difference between the input signal S1 inputted to the input portion 10, and a signal S7 outputted from the frequency divider 60, and outputs a signal S3 (hereinafter, referred to as “phase difference signal S3”), which indicates the phase difference, to the charge pump 30.

The charge pump 30 generates an electric current corresponding to the phase difference signal S3 which is outputted from the phase comparator 20, and outputs an electric current S4 to the filter 40.

The filter 40 is composed of a low pass filter, i.e., an integrating circuit, and smoothly outputs a voltage S5 corresponding to the amount of the electric current S4 supplied from the charge pump 30, to the voltage controlled oscillator 50.

The voltage controlled oscillator 50 is composed of a so-called VCO (Voltage Controlled Oscillator), generates an oscillation signal S6 having a frequency provided by a voltage S5 that is outputted from the filter 40, and outputs the oscillation signal S6 to the frequency divider 60, while outputting an oscillation signal S2, which is the same as the oscillation signal S6, to the output portion 70.

The frequency divider 60 outputs a frequency division signal S7 obtained by dividing-by-N (N is an arbitrary positive number) the oscillation signal S6 outputted from the voltage controlled oscillator 50, to the phase comparator 20.

The output portion 70 outputs the oscillation signal S2 outputted from the voltage controlled oscillator 50 to an external circuit, for example, to a frequency conversion circuit (not shown) for a cellular phone ASIC, an LCD panel ASIC, and/or a low power microcomputer for a clock.

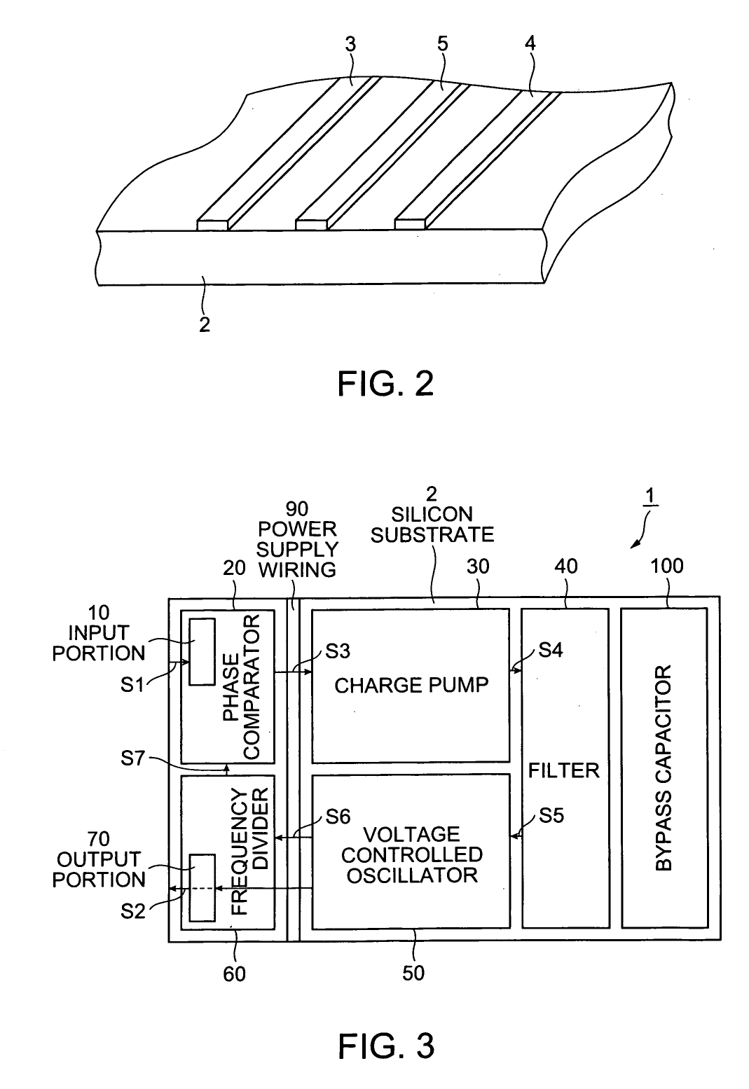

FIG. 2 is a view schematically showing the PLL circuit wiring of embodiment 1. In the PLL circuit 1 of embodiment 1 having a multilayer structure, the plurality of functional blocks 10 through 70 are arranged so that a metal wiring 3 for transferring any of the signals S1 through S7 illustrated in FIG. 1, and a metal wiring 4 for transferring any of the other signals S1 through S7 extend parallel to each other on the silicon substrate 2 surface, i.e., in the same layer, as shown in FIG. 2, in other words, do not cross between different layers. Moreover, a shield wiring 5 is provided between both metal wirings 3 and 4 to prevent signal interference between both metal wirings 3 and 4.

FIG. 3 is a view showing an arrangement of functional blocks in the PLL circuit of embodiment 1. In the PLL circuit 1 of embodiment 1, as shown in FIG. 3, the phase comparator 20 through the frequency divider 60, which are the functional blocks, are arranged on the silicon substrate 2 in order, following the flow of the signals S3 through S7 shown in FIG. 1, and in addition, the input portion 10 and the output portion 70 are arranged so that the wiring for the signal S1 and the wiring for the signal S2 do not cross, i.e., both wirings for the signals S1 and S2 extend in the same layer. Putting the entire arrangement in other words, the input portion 10 through the output portion 70 are arranged so that the metal wirings 3 and 4 illustrated in FIG. 2 corresponding to the wirings for the signals S1 through S7 do not cross.

In addition, a bypass capacitor 100 to be coupled between a power supply wiring 90 for supplying electric power to the input portion 10 through the output portion 70, and a ground potential, which has a conventionally known function, is arranged adjacent to the filter 40. More precisely, the bypass capacitor 100 is arranged on the outside of the filter 40, i.e., on the outside of a closed region virtually formed by joining the phase comparator 20 through the frequency divider 60 in this order.

As described above, in the PLL circuit 1 of embodiment 1, the phase comparator 20 through the frequency divider 60 are arranged so that the wirings for the signals S3 through S7, which are the wirings between the functional blocks 20 through 60, do not cross each other, i.e., extend in the same layer, it is not necessary to provide a shield wiring, which would be needed if the wirings for the signals S3 through S7 crossed each other, for avoiding interference between the signals. Therefore, unlike conventionally, the width of the silicon substrate 2 illustrated in FIG. 2 and FIG. 3, i.e., the area of the silicon substrate 2 can be reduced.

In addition, because the input portion 10 and the output portion 70 are arranged so that the wiring for the signal S1 and the wiring for the signal S2, which are not the wiring between the functional blocks, do not cross each other, i.e., extend in the same layer, it is not necessary to provide a shield wiring, which would be needed if both wirings for the signals S1 and S2 crossed, and as a result, the area of the silicon substrate 2 illustrated in FIG. 2 and FIG. 3 can be reduced.

Moreover, because the wirings for the signals S1 through S7 do not cross, the wirings for the signals S1 through S7 are short as compared with the conventional art, and thereby the wiring resistance can be reduced, and as a result, the crosstalk between the signals can be reduced and the electric current consumed can be also reduced.

Furthermore, because the bypass capacitor 100 is provided near the filter 40, modifications to the function of the filter 40 and the function of the bypass capacitor 100 can be easily made by changing the wiring connection between the bypass capacitor 100 and the capacitor in the filter 40.

The above described modifications to the function can be easily made by arranging the above described bypass capacitor 100 inside the closed region, instead of arranging it outside of the closed region that is virtually formed by joining the phase comparator 20 through the frequency divider 60.

### Embodiment 2

The PLL circuit of embodiment 2 has the input portion 10 through the output portion 70, which are functional blocks like the PLL circuit of embodiment 1, and the functional blocks are mutually coupled by wirings for the signals S1 through S7.

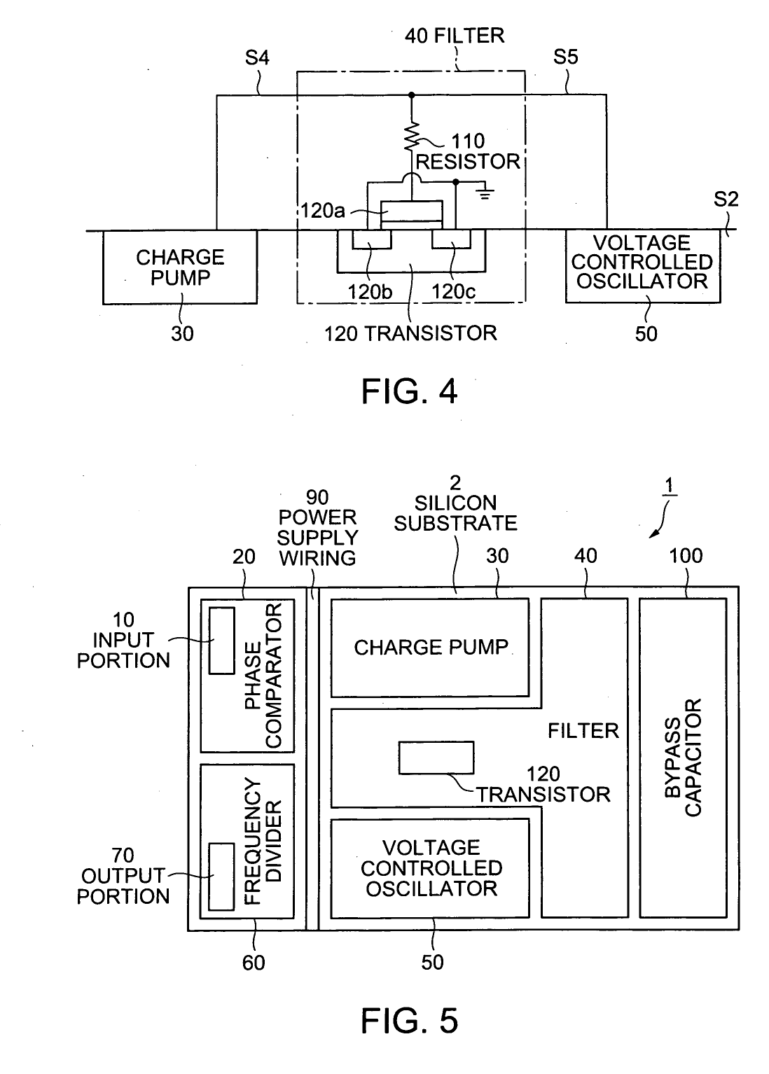

FIG. 4 is a view schematically showing the structure of the PLL circuit of embodiment 2. More particularly, FIG. 4 shows that the charge pump 30, the filter 40, and the voltage controlled oscillator 50 of the PLL circuit 1 of embodiment 2 are constituted in a multilayer structure on the silicon substrate 2. In the PLL circuit 1 of embodiment 2, the filter 40, which is a low pass filter like the filter 40 of embodiment 1, is constituted by a resistor 110 and a transistor 120 which are coupled in series, as shown in FIG. 4.

The transistor 120 is a conventionally known FET (Field Effect Transistor). One end of the resistor 110 is coupled to the wirings for the signals S4 and S5, another end of the resistor 110 is coupled to a gate electrode 120a of the transistor 120, and a drain electrode 120b and a source electrode 120c of the transistor 120 are coupled to a ground potential. The transistor 120 itself functions as a capacitor by the connection of the transistor 120, and functions as a low pass filter cooperating with the resistor 110.

FIG. 5 is a view showing the arrangement of the functional blocks in the PLL circuit of embodiment 2. In the PLL circuit 1 of embodiment 2, as shown in FIG. 5, like embodiment 1, the input portion 10 through the output portion 70 are arranged following the flow of the signals S3 through S7 that are illustrated in the block diagram of FIG. 1, so the wirings for the signals S1 through S7 do not cross each other, and the bypass capacitor 100 is arranged on the outside of the filter 40. In the PLL circuit 1 of embodiment 2, a part of the filter 40, more precisely, the transistor 120 illustrated in the FIG. 4 which constitutes the filter 40, is provided between the charge pump 30 and the voltage controlled oscillator 50, and thereby the mutual distance between the charge pump 30 and the voltage controlled oscillator 50 is made long as compared with the mutual distances of the others, for example, the mutual distance between the charge pump 30 and the filter 40, and the mutual distance between the phase comparator 20 and the frequency divider 60.

As described above, in the PLL circuit 1 of embodiment 2, because the input portion 10 through the output portion 70 are arranged like embodiment 1 so that the wirings for the signals S1 through S7 do not cross each other, and in addition, because the distance between the charge pump 30 and the voltage controlled oscillator 50 is long as compared with the distances between other functional blocks as described above, the occurrence of signal interference between the charge pump 30, which is sensitive to signal interference, and the voltage controlled oscillator 50, can be suppressed.

Moreover, in the PLL circuit 1 of embodiment 2, because the transistor 120 which functions as a capacitor for the filter 40 is arranged between the charge pump 30 and the voltage controlled oscillator 50, the free space of the charge pump 30 and the voltage controlled oscillator 50 can be utilized effectively.

### Embodiment 3

The PLL circuit of embodiment 3 has the input portion 10 through the output portion 70 like the PLL circuit of embodiment 1 and embodiment 2, and the input portion 10 through the output portion 70 are mutually coupled by the wirings for the signals S1 through S7 like embodiment 1 and embodiment 2.

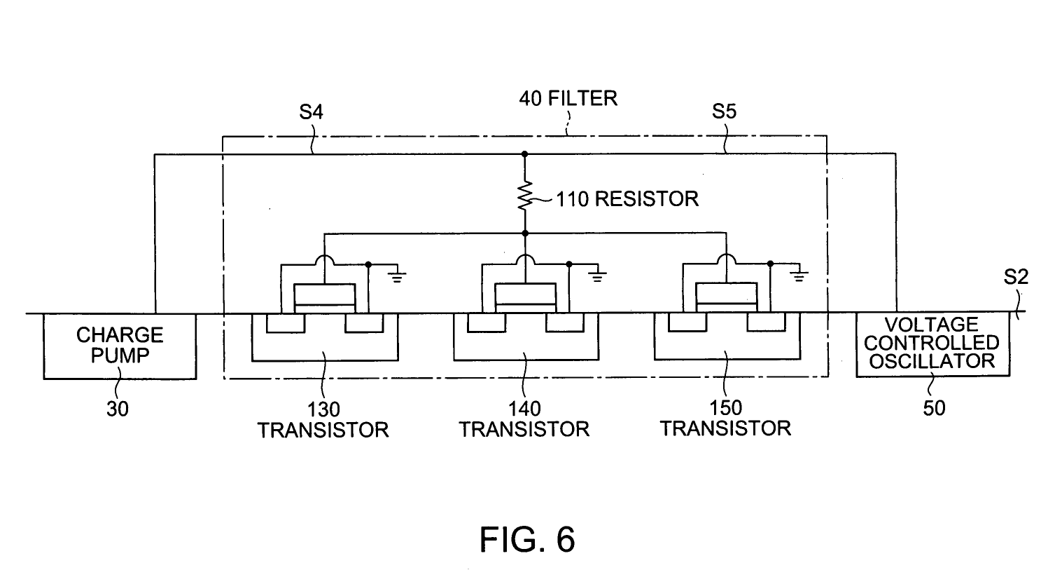

FIG. 6 is a view schematically showing the structure of the PLL circuit of embodiment 3. More particularly, FIG. 6 shows, like FIG. 4, that the charge pump 30, the filter 40, and the voltage controlled oscillator 50 of the PLL circuit 1 of embodiment 3 are formed in a multilayer structure on the silicon substrate 2. In the PLL circuit 1 of embodiment 3, the filter 40 of embodiment 3 is, unlike the filter 40 of embodiment 2, coupled in series to the resistor 110, and composed of three transistors 130, 140, and 150 which are mutually coupled in parallel.

The transistors 130, 140, and 150 actually function in the same manner as the capacitor which is the function of the transistor 120 of embodiment 2 by mutually cooperating and functioning, and thereby, the resistor 110 and the transistors 130, 140, and 150 play a role as a low pass filter, as the entire filter 40.

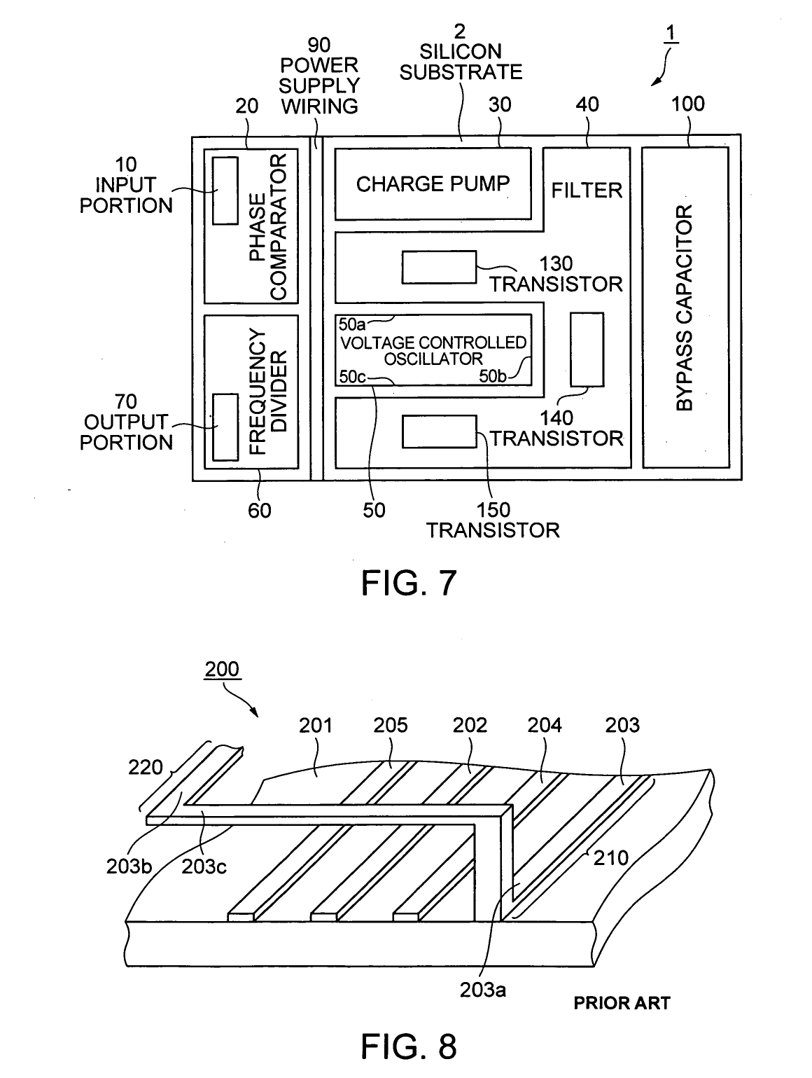

FIG. 7 is a view showing an arrangement of the functional blocks in the PLL circuit of embodiment 3. In the PLL circuit 1 of embodiment 3, as shown in FIG. 7, like embodiment 1 and embodiment 2, the input portion 10 through the output portion 70 are arranged following the flow of the signals S3 through S7 as illustrated in FIG. 1, and so that the wirings for the signals S1 through S7 do not cross each other, and the bypass capacitor 100 is arranged on the outside of the filter 40.

In addition, the transistor 130 illustrated in FIG. 6 is arranged near one side 50a of the voltage controlled oscillator 50, i.e., between the charge pump 30 and the voltage controlled oscillator 50, and the transistor 140 illustrated in FIG. 6 is arranged near other one side 50b of the voltage controlled oscillator 50, and furthermore, the transistor 150 illustrated in FIG. 6 is additionally arranged near the other one side 50c of the voltage controlled oscillator 50. In other words, the transistors 130, 140, and 150 are arranged to encompass the voltage controlled oscillator 50 in the periphery of the voltage controlled oscillator 50.

As described above, in the PLL circuit 1 of embodiment 3, like embodiment 1 and embodiment 2, the input portion 10 through the output portion 70 are arranged so that the wirings for the signals S1 through S7 do not cross each other, and in addition, because the transistors 130, 140, and 150 which constitute the filter 40 are arranged near the voltage controlled oscillator 50, the voltage controlled oscillator 50, which easily gives and receives signal interference, can be effectively isolated from the other functional blocks, and thereby, signal interference between the voltage controlled oscillator 50 and the other functional blocks can be reduced as compared with the conventional art.

Although the description above has been made with reference to preferred embodiments, it should be understood that various modifications may be made to the embodiments without departing from the spirit and scope of the present invention.

1. A semiconductor device comprising:
a plurality of circuits constituted by a multilayer structure on a substrate;
wherein the plurality of circuits include:
one wiring of a plurality of wirings among the plurality of circuits in one layer of the multilayer structure;
another wiring of the plurality of wirings in another layer of the multilayer structure; and
the one wiring and the other wiring do not cross each other.

2. A semiconductor device comprising:
a plurality of circuits constituted by a multilayer structure on a substrate;
wherein the plurality of circuits are arranged so that one wiring and another wiring of a plurality of wirings among the plurality of circuits extend in the same layer of the multilayer structure.

3. A PLL circuit comprising:
a phase comparator;
a charge pump;
a filter;
a voltage controlled oscillator; and
a frequency divider constituted by a multilayer structure on a substrate;
wherein one wiring of a plurality of wirings among the phase comparator, the charge pump, the filter, the voltage controlled oscillator, and the frequency divider in one layer of the multilayer structure does not cross another wiring of the plurality of wirings in another layer of the multilayer structure.

4. A PLL circuit comprising:
a phase comparator;
a charge pump;
a filter;
a voltage controlled oscillator; and
a frequency divider constituted by a multilayer structure on a substrate;
wherein one wiring and another wiring of a plurality of wirings among the phase comparator, the charge pump, the filter, the voltage controlled oscillator, and the frequency divider extend in the same layer of the multilayer structure.

5. The PLL circuit according to claim 4, wherein:
the phase comparator, the charge pump, the filter, the voltage controlled oscillator, and the frequency divider are arranged so that the plurality of wirings, an input signal wiring to the phase comparator circuit, and an output signal wiring from the voltage controlled oscillator do not cross each other.

6. The PLL circuit according to claim 4, wherein:
the phase comparator, the charge pump, the filter, the voltage controlled oscillator, and the frequency divider are arranged so that the plurality of wirings, an input signal wiring to the phase comparator circuit, and an output signal wiring from the voltage controlled oscillator extend in the same layer of the multilayer structure.

7. The PLL circuit according to claim 4, wherein:
a first distance between the charge pump and the voltage controlled oscillator is longer than a second distance between two mutually adjoining members of the group consisting of:
the phase comparator, the charge pump, the voltage controlled oscillator, and the frequency divider.

8. The PLL circuit according to claim 7, wherein a transistor that functions as a capacitor in the filter is provided between the charge pump and the voltage controlled oscillator.

9. The PLL circuit according to claim 7, wherein a plurality of transistors that function as a capacitor in the filter are provided in the periphery of the voltage controlled oscillator.

10. The PLL circuit according to claim 4, wherein a bypass capacitor between a power supply wiring for supplying electric power to one of the phase comparator, the charge pump, the filter, the voltage controlled oscillator, and the frequency dividers, and a ground is provided near the filter.

11. The PLL circuit according to claim 10, wherein the bypass capacitor is provided outside of a closed region virtually formed by joining the phase comparator, the charge pump, the filter, the voltage controlled oscillator, and the frequency divider.

12. The PLL circuit according to claim 3, wherein:
the phase comparator, the charge pump, the filter, the voltage controlled oscillator, and the frequency divider are arranged so that the plurality of wirings, an input signal wiring to the phase comparator circuit, and an output signal wiring from the voltage controlled oscillator do not cross each other.

13. The PLL circuit according to claim 3, wherein:
the phase comparator, the charge pump, the filter, the voltage controlled oscillator, and the frequency divider are arranged so that the plurality of wirings, an input signal wiring to the phase comparator circuit, and an output signal wiring from the voltage controlled oscillator extend in the same layer of the multilayer structure.

14. The PLL circuit according to claim 3, wherein:
a first distance between the charge pump and the voltage controlled oscillator is longer than a second distance between two mutually adjoining two members of the group consisting of:
the phase comparator, the charge pump, the voltage controlled oscillator, and the frequency divider.

15. The PLL circuit according to claim 14, wherein a transistor that functions as a capacitor in the filter is provided between the charge pump and the voltage controlled oscillator.

16. The PLL circuit according to claim 14, wherein a plurality of transistors that function as a capacitor in the filter are provided in the periphery of the voltage controlled oscillator.

17. The PLL circuit according to claim 3, wherein a bypass capacitor between a power supply wiring for supplying electric power to one of the phase comparator, the charge pump, the filter, the voltage controlled oscillator, and the frequency dividers, and a ground is provided near the filter.

18. The PLL circuit according to claim 17, wherein the bypass capacitor is provided outside of a closed region virtually formed by joining the phase comparator, the charge pump, the filter, the voltage controlled oscillator, and the frequency divider.
